(19) United States
(12) Patent Application Publication
(10) Pub. No.: US 2011/0275200 A1
(43) Pub. Date: Nov. 10, 2011

(54) METHODS OF DYNAMICALLY CONTROLLING FILM MICROSTRUCTURE FORMED IN A MICROCRYSTALLINE LAYER

(75) Inventors: Yi Zheng, Sunnyvale, CA (US); Guangchi Xuan, Santa Clara, CA (US); Zheng Yuan, Cupertino, CA (US); Brian Shieh, Palo Alto, CA (US)

(73) Assignee: APPLIED MATERIALS, INC., Santa Clara, CA (US)

(21) Appl. No.: 13/098,072

(22) Filed: Apr. 29, 2011

Related U.S. Application Data
(60) Provisional application No. 61/332,055, filed on May 6, 2010.

(51) Int. Cl. H01L 21/205

(52) U.S. Cl. 438/488; 257/E21.102

(57) ABSTRACT

A method for an intrinsic type microcrystalline silicon layer is provided. In one embodiment, a method for forming an intrinsic type microcrystalline silicon layer includes dynamically ramping up a silane gas supplied in a gas mixture to a surface of a substrate disposed in a processing chamber, dynamically ramping down a RF power applied in the gas mixture supplied to the processing chamber to form a plasma in the gas mixture, and forming an intrinsic type microcrystalline silicon layer on the substrate.

### CROSS-REFERENCE TO RELATED APPLICATIONS

This application claims benefit of U.S. Provisional Application Ser. No. 61/332,055 filed May 6, 2010 (Attorney Docket No. APPM/15167L), which is incorporated by reference in its entirety.

### BACKGROUND OF THE INVENTION

1. Field of the Invention

Embodiments of the present invention generally relate to solar cells and methods for forming the same. More particularly, embodiments of the present invention relate to a method of forming a microcrystalline silicon layer utilized in solar applications.

2. Description of the Related Art

Photovoltaic devices (PV) or solar cells are devices which convert sunlight into direct current (DC) electrical power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are created by connecting a number of PV solar cells and are then joined into panels with specific frames and connectors.

Microcrystalline silicon film (μc-Si) is one type of film being used to form PV devices. However, a production worthy process has yet to be developed to be able to provide PV devices at high deposition rate and high film quality as well as low manufacturing cost. For example, insufficient crystallinity of the silicon film may cause incomplete formation and fraction of the film, thereby reducing the conversion efficiency in a PV solar cell. Additionally, conventional deposition processes of microcrystalline silicon film (μc-Si), have slow deposition rates, which disadvantageously reduce manufacturing throughput and increase production costs.

Therefore, there is a need for an improved method for depositing a microcrystalline silicon film.

### SUMMARY OF THE INVENTION

Embodiments of the invention provide methods for forming solar cells. In one embodiment, a method for forming an intrinsic type microcrystalline silicon layer includes dynamically ramping up a silane gas supplied in a gas mixture to a surface of a substrate disposed in a processing chamber, dynamically ramping down a RF power applied in the gas mixture supplied to the processing chamber, the gas mixture forming a plasma in the processing chamber, and forming an intrinsic type microcrystalline silicon layer on the substrate in the presence of the plasma.

In another embodiment, a method for forming an intrinsic type microcrystalline silicon layer includes forming an intrinsic type seed layer on a substrate disposed in a processing chamber, applying a RF power less than 400 milliWatts/cm² to maintain a plasma formed from a gas mixture while forming the seed layer, subsequently forming an intrinsic type microcrystalline silicon layer on the substrate in the presence of the plasma, wherein the intrinsic type microcrystalline silicon layer is formed by dynamically ramping up a silane gas supplied in the gas mixture, and dynamically ramping down a RF power applied in the gas mixture supplied to the processing chamber to form a plasma in the gas mixture.

In yet another embodiment, a method for forming an intrinsic type microcrystalline silicon layer includes supplying a first gas mixture onto a surface of a substrate disposed in a processing chamber to form an intrinsic type seed layer on the substrate, wherein a first gas mixture includes a silane gas and a hydrogen gas, the silane gas flow rate is ramped up and the hydrogen gas flow rate is maintained steady while supplying the first gas mixture, and supplying a second gas mixture onto the surface of the substrate to form an intrinsic type microcrystalline silicon layer on the intrinsic type seed layer, wherein the silane gas flow rate is ramped up while supplying the second gas mixture and a RF power applied to the second gas mixture is ramped down while forming the intrinsic type microcrystalline silicon layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a schematic side-view of a tandem junction thin-film solar cell having an intrinsic type microcrystalline silicon layer formed within the solar cell according to one embodiment of the invention;

FIG. 2 is a schematic side-view of a single junction thin-film solar cell having an intrinsic type microcrystalline silicon layer formed within the solar cell according to one embodiment of the invention;

FIG. 3 is a cross-sectional view of an apparatus according to one embodiment of the invention;

FIG. 4 is a process flow describing a method to deposit an intrinsic type microcrystalline silicon layer by dynamically controlling process parameters utilized during depositing according to one embodiment of the invention;

FIG. 5 is a plan view of a system having the apparatus of FIG. 3 incorporated therein according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention describes a method to deposit an intrinsic type microcrystalline silicon layer with high deposition rate and uniform crystalline fraction. In one embodiment, the intrinsic type microcrystalline silicon layer may be deposited by dynamically controlling process parameters utilized during the depositing process to dynamically control the film properties and microstructures formed in the resultant intrinsic type microcrystalline silicon layer. In one embodiment, the intrinsic type microcrystalline silicon layer may be used in a multi-junction solar cell or a single junction solar cell.

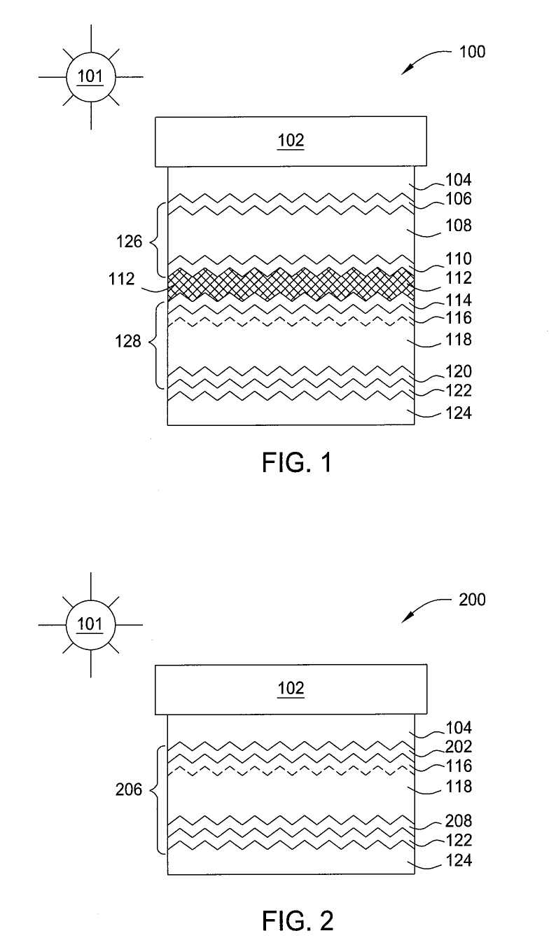

FIG. 1 is a schematic diagram of an embodiment of a multi-junction solar cell 100 oriented toward the light or solar radiation 101. Solar cell 100 comprises a substrate 102, such as a glass substrate, polymer substrate, metal substrate, or other suitable substrate, with thin films formed thereover. The solar cell 100 further comprises a first transparent conducting oxide (TCO) layer 104 formed over the substrate 102 and a first p-i-n junction 126 formed over the first TCO layer 104. In one configuration, an optional wavelength selective reflector (WSR) layer 112 is formed over the first p-i-n junction 126. A second p-i-n junction 128 may be formed over the first p-i-n junction 126, a second TCO layer 122 may be formed over the second p-i-n junction 128, and a metal back layer 124 may be formed over the second TCO layer 122. To improve light absorption by enhancing light trapping, the substrate and/or one or more of thin films formed thereover may be optionally textured by wet, plasma, ion, and/or mechanical processes. For example, in the embodiment shown in FIG. 1, the first TCO layer 104 is textured so that the thin films subsequently deposited thereover will generally reproduce the topography of the surface below it.

The first TCO layer 104 and the second TCO layer 122 may each comprise tin oxide, zinc oxide, indium tin oxide, cadmium stannate, combinations thereof, or other suitable materials. It is understood that the TCO layer material may also include additional dopants and components. For example, zinc oxide may further include dopants, such as aluminum, gallium, boron, and other suitable dopants. Zinc oxide may comprise 5 atomic % or less of dopants, such as comprising about 2.5 atomic % or less aluminum. In certain instances, the substrate 102 may be provided by the glass manufacturers with the first TCO layer 104 already deposited thereon.

The first p-i-n junction 126 may comprise a p-type amorphous silicon layer 106, an intrinsic type amorphous silicon layer 108 formed over the p-type amorphous silicon layer 106, and an n-type microcrystalline silicon layer 110 formed over the intrinsic type amorphous silicon layer 108. In certain embodiments, the p-type amorphous silicon layer 106 may be formed to a thickness between about 60 Å and about 300 Å. In certain embodiments, the intrinsic type amorphous silicon layer 108 may be formed to a thickness between about 1,500 Å and about 3,500 Å. In certain embodiments, the n-type microcrystalline semiconductor layer 110 may be formed to a thickness between about 100 Å and about 400 Å.

The WSR layer 112 disposed between the first p-i-n junction 126 and the second p-i-n junction 128 is generally configured to have certain desired film properties. In one configuration, the WSR layer 112 actively serves as an intermediate reflector having a desired refractive index, or ranges of refractive indexes, to reflect light received from the light incident side of the solar cell 100. The WSR layer 112 also serves as a junction layer that boosts the absorption of the short to mid wavelengths of light (e.g., 280 nm to 800 nm) in the first p-i-n junction 126 and improves short-circuit current, resulting in improved quantum and conversion efficiency. The WSR layer 112 further has high film transmittance for mid to long wavelengths of light (e.g., 500 nm to 1100 nm) to facilitate the transmission of light to the layers formed in the junction 128. In one embodiment, the WSR layer 112 may be a microcrystalline silicon layer having n-type or p-type dopants disposed within the WSR layer 112. In an exemplary embodiment, the WSR layer 112 is an n-type crystalline silicon alloy having n-type dopants disposed within the WSR layer 112. Different dopants disposed within the WSR layer 112 may also influence optical and electrical properties, such as bandgap, crystalline fraction, conductivity, transparency, film refractive index, extinction coefficient, and the like. In some instances, one or more dopants may be doped into various regions of the WSR layer 112 to efficiently control and adjust the film bandgap, work function(s), conductivity, transparency and so on. In one embodiment, the WSR layer 112 is controlled to have a refractive index between about 1.4 and about 3, a bandgap of at least about 2 eV, and a conductivity greater than about 10⁻³ S/cm.

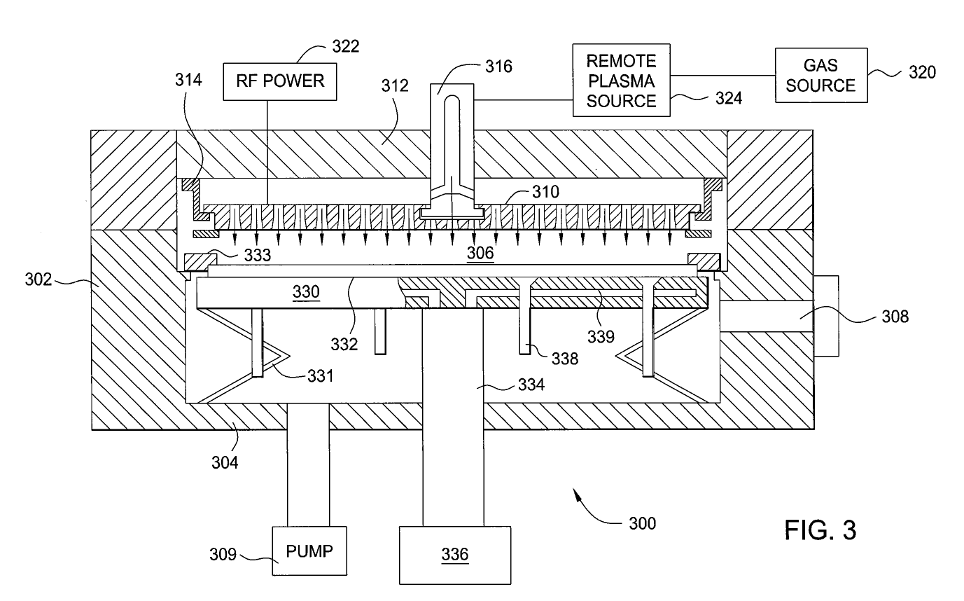

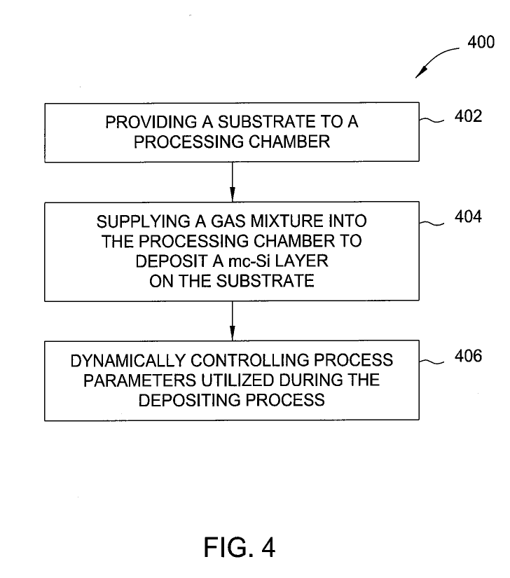

The second p-i-n junction 128 may comprise a p-type microcrystalline silicon layer 114, an intrinsic type microcrystalline silicon layer 118 formed over the p-type microcrystalline silicon layer 114, and an n-type amorphous silicon layer 120 formed over the intrinsic type microcrystalline silicon layer 118. In one embodiment, prior to the deposition of the bulk layer of the intrinsic type microcrystalline silicon layer 118, an intrinsic microcrystalline silicon seed layer 116 may be formed over the p-type microcrystalline silicon layer 114. In one embodiment, the seed layer 116 and the intrinsic type microcrystalline silicon layer 118 may be formed in a process by utilizing different process parameters during deposition performed in a processing chamber to form the layers 116, 118 individually. More details regarding how to deposit the seed layer 116 and the bulk intrinsic type microcrystalline silicon layer 118 will be further described below with referenced to FIGS. 3-4.

In one embodiment, the p-type microcrystalline silicon layer 114 may be formed to a thickness between about 100 Å and about 400 Å. In certain embodiments, the intrinsic microcrystalline silicon seed layer 116 may be formed to a thickness between about 50 Å and about 500 Å. In certain embodiments, the bulk intrinsic type microcrystalline silicon layer 118 may be formed to a thickness between about 10,000 Å and about 30,000 Å. In certain embodiments, the n-type amorphous silicon layer 120 may be formed to a thickness between about 100 Å and about 500 Å.

The metal back layer 124 may include, but not limited to a material selected from the group consisting of Al, Ag, Ti, Cr, Au, Cu, Pt, alloys thereof, or combinations thereof. Other processes may be performed to form the solar cell 100, such a laser scribing processes. Other films, materials, substrates, and/or packaging may be provided over metal back layer 124 to complete the solar cell device. The formed solar cells may be interconnected to form modules, which in turn can be connected to form arrays.

Solar radiation 101 is primarily absorbed by the intrinsic layers 108, 118 of the p-i-n junctions 126, 128 and is converted to electron-holes pairs. The electric field created between the p-type layer 106, 114 and the n-type layer 110, 120 that stretch across the intrinsic layer 108, 118 causes electrons to flow toward the n-type layers 110, 120 and holes to flow toward the p-type layers 106, 114 creating a current. The first p-i-n junction 126 comprises an intrinsic type amorphous silicon layer 108 and the second p-i-n junction 128 comprises an intrinsic type microcrystalline silicon layer 118 since amorphous silicon and microcrystalline silicon absorb different wavelengths of the solar radiation 101. Therefore, the formed solar cell 100 is more efficient, since it captures a larger portion of the solar radiation spectrum. The intrinsic layer 108, 118 of amorphous silicon and the intrinsic layer of microcrystalline are stacked so that solar radiation 101 first strikes the intrinsic type amorphous silicon layer 118 and transmitted through the WSR layer 112 and then strikes the intrinsic type microcrystalline silicon layer 118 since amorphous silicon has a larger bandgap than microcrystalline silicon. Solar radiation not absorbed by the first p-i-n junction 126 continuously transmits through the WSR layer 112 and continues on to the second p-i-n junction 128.

Charge collection is generally provided by doped semiconductor layers, such as silicon layers doped with p-type or n-type dopants. P-type dopants are generally group III elements, such as boron or aluminum. N-type dopants are generally group V elements, such as phosphorus, arsenic, or antimony. In most embodiments, boron is used as the p-type dopant and phosphorus as the n-type dopant. These dopants may be added to the p-type and n-type layers 106, 110, 114, 120 described above by including boron-containing or phosphorus-containing compounds in the reaction mixture. Suitable boron and phosphorus compounds generally comprise substituted and unsubstituted lower borane and phosphine oligomers. Some suitable boron compounds include trimethylboron (B(CH₃)₃ or TMB), diborane (B₂H₆), boron trifluoride (BF₃), and triethylboron (B(C₂H₅)₃ or TEB). Phosphine is a common phosphorus compound. The dopants are generally provided with carrier gases, such as hydrogen, helium, argon, and other suitable gases. If hydrogen is used as the carrier gas, the total hydrogen in the reaction mixture will be increased. Thus hydrogen ratios will include hydrogen used as a carrier gas for dopants.

Dopants will generally be provided as diluted gas mixtures in an inert gas. For example, dopants may be provided at molar or volume concentrations of about 0.5% in a carrier gas. If a dopant is provided at a volume concentration of 0.5% in a carrier gas flowing at 1.0 sccm/L, the resultant dopant flow rate will be 0.005 sccm/L. Dopants may be provided to a reaction chamber at flow rates between about 0.0002 sccm/L and about 0.1 sccm/L depending on the degree of doping desired. In general, dopant concentration is maintained between about 10¹⁸ atoms/cm² and about 10²⁰ atoms/cm².

In one embodiment, the p-type microcrystalline silicon layer 114 may be deposited by providing a gas mixture of hydrogen gas and silane gas in ratio of hydrogen-to-silane of about 200:1 or greater, such as 1000:1 or less, for example between about 250:1 and about 800:1, and in a further example about 601:1 or about 401:1. Silane gas may be provided at a flow rate between about 0.1 sccm/L and about 0.8 sccm/L, such as between about 0.2 sccm/L and about 0.38 sccm/L. Hydrogen gas may be provided at a flow rate between about 60 sccm/L and about 500 sccm/L, such as about 143 sccm/L. TMB may be provided at a flow rate between about 0.0002 sccm/L and about 0.0016 sccm/L, such as about 0.00115 sccm/L. If TMB is provided in a 0.5% molar or volume concentration in a carrier gas, then the dopant/carrier gas mixture may be provided at a flow rate between about 0.04 sccm/L and about 0.32 sccm/L, such as about 0.23 sccm/L. RF power may be applied between about 50 mW/cm² and about 700 mW/cm², such as between about 290 mW/cm² and about 440 mW/cm². Chamber pressure may be maintained between about 1 Torr and about 100 Torr, such as between about 3 Torr and about 20 Torr, for example between 4 Torr and about 12 Torr, such as about 7 Torr or about 9 Torr. These conditions will deposit a p-type microcrystalline layer having crystalline fraction between about 20 percent and about 80 percent, such as between 50 percent and about 70 percent at a rate of about 10 Å/min or more, such as about 143 Å/min or more.

In one embodiment, a second dopant, such as carbon, germanium, nitrogen, oxygen, in the p-type microcrystalline silicon layer 114 may improve photoelectronic conversion efficiency. Details regarding how a second dopant can improve the overall solar cell performance is disclosed in detail by U.S. patent application Ser. No. 12/208,478, filed Sep. 11, 2008 with the title “Microcrystalline Silicon Alloys for Thin Film and Wafer Based Solar Applications,” which is herein incorporated by reference

In one embodiment, the p-type amorphous silicon layer 106 may be deposited by providing a gas mixture of hydrogen gas to silane gas in a ratio of about 20:1 or less. Silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. If trimethylboron is provided in a 0.5% molar or volume concentration in a carrier gas, then the dopant/carrier gas mixture may be provided at a flow rate between about 1 sccm/L and about 10 sccm/L. RF power may be applied between about 15 mWatts/cm² and about 200 mWatts/cm². Chamber pressure may be maintained between about 0.1 Torr and 20 Torr, such as between about 1 Torr and about 4 Torr, to deposit a p-type amorphous silicon layer at about 100 Å/min or more from the gas mixture.

In one embodiment, the n-type microcrystalline silicon layer 110 may be deposited by providing a gas mixture of hydrogen gas to silane gas in a ratio (by volume) of about 100:1 or more, such as about 500:1 or less, such as between about 150:1 and about 400:1, for example about 304:1 or about 203:1. Silane gas may be provided at a flow rate between about 0.1 sccm/L and about 0.8 sccm/L, such as between about 0.32 sccm/L and about 0.45 sccm/L, for example about 0.35 sccm/L. Hydrogen gas may be provided at a flow rate between about 30 sccm/L and about 250 sccm/L, such as between about 68 sccm/L and about 143 sccm/L, for example about 71.43 sccm/L. Phosphine may be provided at a flow rate between about 0.0005 sccm/L and about 0.006 sccm/L, such as between about 0.0025 sccm/L and about 0.015 sccm/L, for example about 0.005 sccm/L. In other words, if phosphine is provided in a 0.5% molar or volume concentration in a carrier gas, then the dopant/carrier gas may be provided at a flow rate between about 0.1 sccm/L and about 5 sccm/L, such as between about 0.5 sccm/L and about 3 sccm/L, for example between about 0.9 sccm/L and about 1.088 sccm/L. RF power may be applied between about 100 mW/cm² and about 900 mW/cm², such as about 370 mW/cm². Chamber pressure may be maintained between about 1 Torr and about 100 Torr, such as between about 3 Torr and about 20 Torr, for example between 4 Torr and about 12 Torr, for example about 6 Torr or about 9 Torr, to deposit an n-type microcrystalline silicon layer having a crystalline fraction between about 20 percent and about 80 percent, for example between 50 percent and about 70 percent, at a rate of about 50 Å/min or more, such as about 150 Å/min or more.

In one embodiment, the n-type amorphous silicon layer 120 may be deposited by providing a gas mixture of hydrogen gas to silane gas in a ratio (by volume) of about 20:1 or less, such as about 5:5:1 or 7.8:1. Silane gas may be provided at a flow rate between about 0.1 sccm/L and about 10 sccm/L, such as between about 1 sccm/L and about 10 sccm/L, between about 0.1 sccm/L and 5 sccm/L, or between about 0.5 sccm/L and about 3 sccm/L, for example about 1.42 sccm/L or 5.5 sccm/L. Hydrogen gas may be provided at a flow rate between about 1 sccm/L and about 40 sccm/L, such as between about 4 sccm/L and about 40 sccm/L, or between about 1 sccm/L and about 10 sccm/L, for example about 6.42 sccm/L or 27 sccm/L. Phosphine may be provided at a flow rate between about 0.0005 sccm/L and about 0.075 sccm/L, such as between about 0.0005 sccm/L and about 0.0015 sccm/L or between about 0.015 sccm/L and about 0.03 sccm/L, for example about 0.0095 sccm/L or 0.023 sccm/L. If phosphine is provided in a 0.5% molar or volume concentration in a carrier gas, then the dopant/carrier gas mixture may be provided at a flow rate between about 0.1 sccm/L and about 15 sccm/L, such as between about 0.1 sccm/L and about 3 sccm/L, between about 2 sccm/L and about 15 sccm/L, or between about 3 sccm/L and about 6 sccm/L, for example about 1.9 sccm/L or about 4.71 sccm/L. RF power may be applied between about 25 mW/cm² and about 250 mW/cm², such as about 60 mW/cm² or about 80 mW/cm². Chamber pressure between about 0.1 Torr and about 20 Torr, such as between about 0.5 Torr and about 4 Torr, such as about 1.5 Torr, will deposit an n-type amorphous silicon layer at a rate of about 100 Å/min or more, such as about 200 Å/min or more, such as about 300 Å/min or about 600 Å/min.

In some embodiments, the silicon layers may be heavily doped or degenerately doped by supplying dopant compounds at high rates, for example at rates in the upper part of the recipes described above. It is thought that degenerate doping improves charge collection by providing low-resistance contact junctions. Degenerate doping is also thought to improve conductivity of some layers, such as amorphous layers.

In one embodiment, the intrinsic amorphous silicon layer 108 may be deposited by providing a gas mixture of hydrogen gas to silane gas in a ratio (by volume) of about 20:1 or less. Silane gas may be provided at a flow rate between about 0.5 sccm/L and about 7 sccm/L. Hydrogen gas may be provided at a flow rate between about 5 sccm/L and 60 sccm/L. An RF power between 15 mW/cm² and about 250 mW/cm² may be provided to the showerhead. The pressure of the chamber may be maintained between about 0.1 Torr and 20 Torr, such as between about 0.5 Torr and about 5 Torr. The deposition rate of the intrinsic type amorphous silicon layer 108 may be about 100 Å/min or more. In an exemplary embodiment, the intrinsic type amorphous silicon layer 108 is deposited at a hydrogen to silane ratio of about 12.5:1.

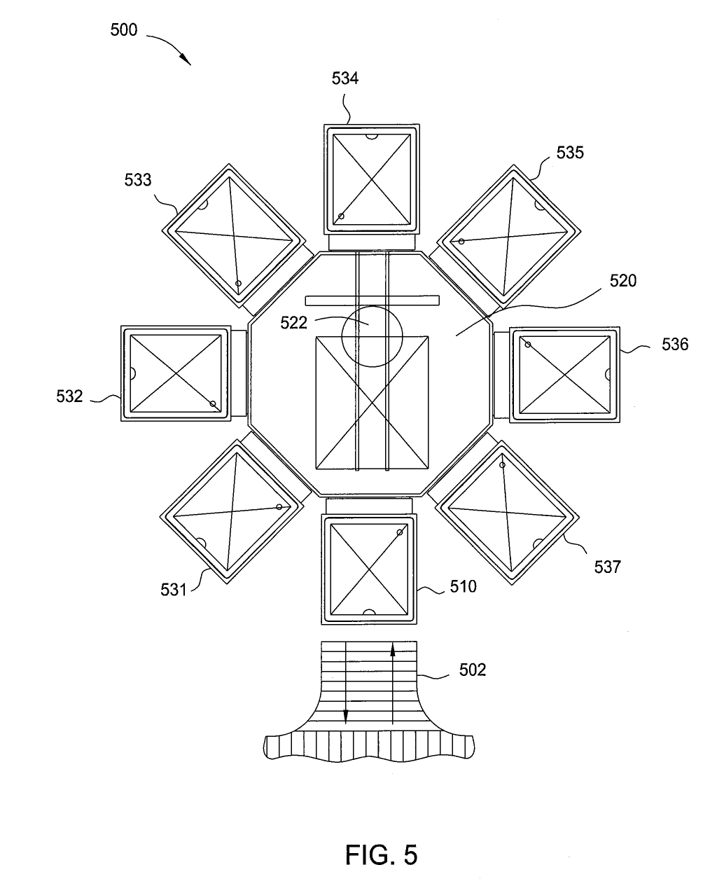

Further details regarding deposition of the intrinsic type microcrystalline silicon seed layer 116 and the intrinsic type microcrystalline silicon layer 118 will be further described below with referenced to FIGS. 4-5.

FIG. 2 is a schematic diagram of an embodiment of a single junction solar cell 200 having the intrinsic type microcrystalline silicon seed layer 116 and the intrinsic type microcrystalline silicon layer 118. Solar cell 200 comprises the substrate 102, the first transparent conducting oxide (TCO) layer 104 formed over the substrate 102, a single p-i-n junction 206 formed over the first TCO layer 104. The second TCO layer 122 is formed over the single p-i-n junction 206, and a metal back layer 124 formed over the second TCO layer 122. In one embodiment, the single p-i-n junction 206 includes a p-type silicon layer 202, the intrinsic type microcrystalline silicon seed layer 116 and the intrinsic type microcrystalline silicon layer 118, and a n-type silicon layer 208 formed over the intrinsic type microcrystalline silicon layer 118. The p-type 202 and the n-type silicon layer 208 may be any types of silicon layers, including amorphous silicon, microcrystalline silicon, polysilicon, and so on, utilized to form the p-i-n junction 206. The detail description regarding how the intrinsic type microcrystalline silicon seed layer 116 and the intrinsic type microcrystalline silicon layer 118 may be formed will be further discussed below with referenced to FIGS. 3-4.

FIG. 3 is a schematic cross-section view of one embodiment of a plasma enhanced chemical vapor deposition (PECVD) chamber 300 in which the intrinsic type microcrystalline silicon seed layer 116 and the intrinsic type microcrystalline silicon layer 118 as described in FIGS. 1 and 2 may be deposited. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The PECVD chamber 300 generally includes walls 302, a bottom 304, and a showerhead 310, and substrate support 330 which define a process volume 306. The process volume is accessed through a valve 308 such that the substrate may be transferred in and out of the PECVD chamber 300. The substrate support 330 includes a substrate receiving surface 332 for supporting a substrate and stem 334 coupled to a lift system 336 to raise and lower the substrate support 330. A shadow ring 333 may be optionally placed over periphery of the substrate 102. Lift pins 338 are moveably disposed through the substrate support 330 and may be actuated to space the substrate from the substrate receiving surface 332 to facilitate robotic transfer. The substrate support 330 may also include heating and/or cooling elements 339 to maintain the substrate support 330 at a desired temperature. The substrate support 330 may also include RF conductive straps 331 to provide an RF return path at the periphery of the substrate support 330.

The showerhead 310 is coupled to a backing plate 312 at its periphery by a suspension 314. The showerhead 310 may also be coupled to the backing plate by one or more center supports 316 to help prevent sag and/or control the straightness/curvature of the showerhead 310. A gas source 320 is coupled to the backing plate 312 to provide gas through the backing plate 312 and through the showerhead 310 to the substrate receiving surface 332. A vacuum pump 309 is coupled to the PECVD chamber 300 to control the process volume 306 at a desired pressure. An RF power source 322 is coupled to the backing plate 312 and/or to the showerhead 310 to provide a RF power to the showerhead 310. The RF power creates an electric field between the showerhead and the substrate support 330 so that a plasma may be generated from the gases between the showerhead 310 and the substrate support 330. Various RF frequencies may be used, such as a frequency between about 0.3 MHz and about 200 MHz. In one embodiment the RF power source is provided at a frequency of 13.56 MHz.

A remote plasma source 324, such as an inductively coupled remote plasma source, may also be coupled between the gas source and the backing plate. Between processing substrates, a cleaning gas may be provided to the remote plasma source 324 which generates a remote plasma that is provided to clean chamber components in the process volume 306. The cleaning gas may be further excited by the RF power source 322 provided to the showerhead. Suitable cleaning gases include but are not limited to NF₃, F₂, and SF₆.

The deposition methods for intrinsic type microcrystalline silicon layers, such as microcrystalline silicon layers 116, 118 of FIGS. 1-2, may include the following deposition parameters in the process chamber of FIG. 3 or other suitable chamber. A substrate having a surface area of 10,000 cm² or more, for example 40,000 cm² or more, and such as 55,000 cm² or more is provided to the chamber. It is understood that after processing the substrate may be cut to form smaller solar cells.

In one embodiment, the heating and/or cooling elements 339 may be set to provide a substrate support temperature during deposition of about 400° C. or less, such as between about 100° C. and about 400° C., for example between about 150° C. and about 300° C., such as about 200° C. The spacing during deposition between the top surface of a substrate disposed on the substrate receiving surface 332 and the showerhead 310 may be between 400 mil and about 1,200 mil, such as between 400 mil and about 800 mil.

FIG. 4 depicts a process flow of a method 400 for depositing an intrinsic type microcrystalline silicon layer, such as the intrinsic type microcrystalline silicon seed layer 116 and the intrinsic type microcrystalline silicon layer 118. The method 400 may be performed in a plasma chamber, such as the PECVD chamber 300 depicted in FIG. 3. It is noted that the method 400 may be performed in any suitable plasma chamber, including those from other manufacturers.

The method 400 begins at step 402 by providing a substrate, such as the substrate 102 depicted in FIGS. 1-2, into the processing chamber. The substrate 102 may have the first TCO layer 104 and the p-type silicon layer 202 disposed thereon, as depicted in the embodiment of FIG. 2. The p-type silicon layer may be an amorphous silicon layer, a microcrystalline silicon layer, a polysilicon layer, or any other suitable silicon containing layers. Alternatively, the substrate 102 may have the first TCO layer 104, the first p-i-n junction 126, optionally the WSR layer 112, and the p-type microcrystalline silicon layer 114, as depicted in the embodiment of FIG. 1. It is noted that the substrate 102 may have different combination of films, structures or layers previously formed thereon to facilitate forming the intrinsic type microcrystalline silicon layer on the substrate 102 to form solar cells. In one embodiment, the substrate 102 may be any one of a glass substrate, a plastic substrate, a polymer substrate, or other transparent substrate suitable for forming solar cells thereon.

At step 404, a gas mixture is supplied into the processing chamber to sequentially deposit the intrinsic type microcrystalline silicon seed layer 116 and the bulk intrinsic type microcrystalline silicon layer 118. During depositing, the process parameters utilized to ignite and form the plasma in the gas mixture may be dynamically controlled to facilitate depositing the seed layer 116 and the bulk intrinsic type microcrystalline silicon layer 118 with desired film properties and film microstructure. In one embodiment, the gas mixture may include a silicon-based gas and a hydrogen based gas. Suitable silicon based gases include, but are not limited to, silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to, hydrogen gas (H₂). In one embodiment, the silicon based gas described herein is silane (SiH₄) and the hydrogen-based gas described herein is hydrogen (H₂).

In one embodiment, the silicon based gases, such as the silane gas, supplied in the gas mixture may be gradually ramped up from a first predetermined set point to a second predetermined set point during the deposition process. It is noted that the term “ramp up” used herein means gradually increasing a process parameter from a first set point to a second set point over a predetermined time period with a desired ramp-up rate. The term “ramp up” used herein is not a sudden change caused by an action of throttle valve opening and closing.

It is believed that the gradual ramp-up of the silane gas flow in the gas mixture may assist silicon atoms to uniformly adhere and distribute on the substrate surface, thereby forming the seed layer 116 and the intrinsic type microcrystalline silicon layer 118 with desirable film properties and low defect density. Uniform adherence of the silicon atoms with low defect density formed on the substrate surface provides good nucleation sites for the subsequent atoms to nucleate thereon so as to promote crystallinity of the films subsequently formed thereon.

In the embodiment wherein the seed layer 116 is required to be formed at a slow rate so as to maintain the seed layer 116 with low defect density, a low-to-high silane gas flow ramping may be used. Alternatively, the silane gas flow supplied in the gas mixture may be kept steady as needed and the ramp-up of the silane gas flow may be waited until the bulk deposition process. In one embodiment, the silane gas flow supplied at step 404 for forming the seed layer 116 is controlled at between about 0.01 sccm/L and about 0.1 sccm/L, for example about 0.03 sccm/L (about 3000 sccm) for processing about 30 seconds and about 3000 seconds, such as between about 60 seconds and about 1800 seconds. The hydrogen gas flow supplied at step 404 for forming the seed layer 116 is controlled at between about 100000 sccm and about 500000 sccm, for example about 200000 sccm.

In another embodiment, the silane gas and the hydrogen gas may be supplied into the processing chamber at a predetermined gas flow ratio. The predetermined gas flow ratio of hydrogen to silane gas assists the microcrystalline silicon seed layer 116 to be formed with a desired crystalline fraction and grain structure. In one embodiment, the hydrogen to silane gas flow ratio (e.g., flow volume ratio) in the gas mixture is controlled between about 30 and about 300, or between about 20 and about 250, such as about 200. In one particular embodiment, the hydrogen gas supplied in the gas mixture may be provided at a steady rate while the silane gas flow is gradually ramped up until a desired ratio of the silane gas to the hydrogen gas is reached. It is believed that the low silane flow rate in the initial stage of the deposition may assist formation of film crystalline and nucleation sites due to the relatively pure hydrogen plasma environment and/or high hydrogen dilution in the gas mixture. Accordingly, the hydrogen gas may be supplied into the processing chamber prior to the silane gas so as to create the desired high hydrogen dilution plasma environment. Alternatively, the hydrogen flow may start with a relatively high flow rate and then gradually ramped down, similar to the manner for ramping up the silane flow, until the desired ratio of the hydrogen to silane gas flow is reached.

After the seed layer 116 has reached to a desired thickness, the ratio of the hydrogen gas to silane gas may be changed to deposit the bulk intrinsic type microcrystalline silicon layer 118. While forming the bulk intrinsic type microcrystalline silicon layer 118, the silane gas supplied in the gas mixture may be gradually ramped up until a desired gas flow rate has reached. As the crystalline fraction may increase with the increase of the thickness of the bulk intrinsic type microcrystalline silicon layer 118, dynamically adjusting the gas flow ratio during depositing may efficiently tune the crystalline fraction formed in the bulk intrinsic type microcrystalline silicon layer 118 so as to maintain the crystalline fraction formed within a desired range. It is believed that high silane flow rate supplied in the gas mixture may reduce crystalline fraction formed in the bulk intrinsic type microcrystalline silicon layer 118. Accordingly, by gradually ramping up the flow rate of the silane flow supplied in the gas mixture, the crystalline fraction formed in the bulk intrinsic type microcrystalline silicon layer 118 may be compensated by the increase of the film thickness so as to maintain a constant crystalline fraction formed in the bulk intrinsic type microcrystalline silicon layer 118. In one embodiment, the silane gas may be gradually ramped up during the deposition process. For example, the silane gas may be ramped up from 0.03 sccm/L to about 0.035 sccm/L over a period between about 500 seconds and about 2500 seconds. In another embodiment, the silane gas may be gradually ramped up in the processing chamber at a predetermined gas flow ratio to the hydrogen gas. For example, the ratio of the silane gas flow rate to the hydrogen flow rate supplied in the gas mixture is ramped up within a range from about 1:50 to about 1:200, such as from about 1:70 to about 1:80.

The gradual ramp-up of the silane flow for depositing the bulk intrinsic type microcrystalline silicon layer 118 is dynamically controlled so that the gas flow supplied at different stages of the deposition process may be different. Unlike the conventional practice utilizing step-wise process parameter adjustment, the gas flow supplied during the deposition process is varied only in each time segment predefined by an user to step-by-step form multiple layers with different film properties to make up the whole bulk film. In contrast, by utilizing the present invention, the gas flow may be dynamically and constantly varied and adjusted so as to make the resultant bulk intrinsic type microcrystalline silicon layer 118 has smooth transition with different film properties. In one embodiment, the gas flow as supplied may be dynamically controlled to ramp up linearly, or other ramping profiles, such as parabolic, reverse-parabolic, curved, or any other suitable profile, until the resultant bulk intrinsic type microcrystalline silicon layer 118 is formed. In one embodiment, the gas flow supplied to deposit the bulk intrinsic type microcrystalline silicon layer 118 may be linearly supplied and dynamically controlled.

In one embodiment, inert gas or carrier gas, such as He, and Ar, may also be supplied to the processing chamber as needed. Furthermore, if one or more dopants are desired to be formed in the resultant intrinsic type microcrystalline silicon layer, one or more dopant gases, such as CO₂, O₂, N₂O, NO₂, CH₄, CO, H₂, Ge containing precursor, N₂, and the like, are provided to form a silicon alloy microcrystalline silicon layer as needed.

In one embodiment, an optional hydrogen gas treatment process may be performed on the substrate prior to the deposition of the seed layer 116 and the bulk intrinsic type microcrystalline silicon layer 118. The hydrogen treatment process may be performed to treat the underlying layer to suppress surface contamination. Furthermore the plasma treatment process can also improve electrical properties at the interface since the surface defects may be removed or eliminated during the treatment process. When performing the hydrogen treatment process, a hydrogen gas is supplied into the processing chamber with low RF power. The RF power is controlled at a low level to avoid plasma damage to the underlying layer while maintaining a good plasma treatment effect to remove contaminant from the substrate surface. The gas flow for supplying the hydrogen gas or the argon gas is between about 0.1 sccm/L and about 5 sccm/L, for example about 0.5 sccm/L and about 2 sccm/L. The RF power supplied to do the treatment process may be controlled at less than about 150 milliWatts/cm², such as between about 40 milliWatts/cm² and about 80 milliWatts/cm². After the hydrogen treatment process is completed, silane gas in the gas mixture as descried at step 404 may be supplied into the processing chamber and the RF power may be gradually ramped up to deposit the seed layer 116 and the bulk intrinsic microcrystalline silicon layer 118 as described above.

At step 406, several process parameters may be dynamically adjusted while supplying the gas mixture to the process chamber performed at step 404. While supplying the gas mixture into the process gas at step 404, the RF power applied to ignite the plasma in gas mixture may be controlled in a manner that can plasma ionize the gas mixture in a desired manner. In one embodiment, the RF power applied to the processing chamber is controlled below 400 milliWatts/cm² to deposit the seed layer 116. Providing an overly high amount of RF power at the initial stage of the deposition may result in high ion bombardment, which may damage the underlying layers, produce arcing on the substrate surface and the chamber hardware components, and contribute to a non-uniform or overly excited state of the ions formed in the gas mixture, which may result in non-uniform distribution of the atoms on the substrate surface. In order to prevent such occurrences, the RF power is controlled at a level less than 30 KWatts when forming the seed layer 116 to prevent ions from being dissociated in an overly excited or unstable state. In one embodiment, the RF power supplied during the deposition of the seed layer 116 may be maintained steady or dynamically controlled (i.e., ramped up or ramped down) as needed.

After the seed layer 116 is formed on the substrate, the RF power supplied into the processing chamber for forming the bulk intrinsic type microcrystalline silicon layer 118 is controlled from the first set point to the second set point at a predetermined time period. In one embodiment, the RF power supplied for forming the bulk intrinsic type microcrystalline silicon layer 118 is configured to be gradually ramped down. It is believed that the low RF power applied to the processing chamber during deposition will reduce the crystalline fraction formed in the resultant bulk intrinsic type microcrystalline silicon layer 118. Accordingly, in order to maintain a constant film crystalline when the film thickness increases, gradually ramping down of the RF power is performed to compensate the crystalline fraction increased by the film thickness. In one embodiment, the RF power is ramped down from 50000 Watts to about 45000 Watts at a period between about 1000 seconds and about 1800 seconds. If the power unit is represented by power density, the RF power density may be controlled at between about 800 milliWatts/cm² and about 700 milliWatts/cm² at a time period of between about 1000 seconds and about 1800 seconds. A VHF power may be utilized to provide a frequency 10 MHz and about 200 MHz, such as about 13.56 MHz or about 40 MHz to provide sufficient RF power to dissociate ions in the gas mixture so that a high deposition rate may be obtained.

Similar to the control of the gas mixture supplied at step 404, the RF power as applied may be dynamically controlled to maintain the plasma formed in the gas mixture in a desired manner that can form the bulk intrinsic type microcrystalline silicon layer 118 with desired film crystalline fraction. The RF power may be dynamically controlled in any ramping profiles, such as linear, parabolic, reverse-parabolic, curved, or any other suitable profile, until the resultant bulk intrinsic type microcrystalline silicon layer 118 is formed. In one embodiment, the RF power applied to deposit the bulk intrinsic type microcrystalline silicon layer 118 may be linearly ramped down and dynamically controlled.

During the process performed at step 406, several process parameters may be dynamically controlled during deposition process. In one embodiment, the process pressure maintained during the deposition process may be dynamically adjusted throughout the deposition process. In one embodiment, the process pressure may be gradually ramped up to reduce the crystalline fraction formed in the resultant bulk intrinsic type microcrystalline silicon layer 118 when the layer 118 grows. The process pressure may be ramped up from a first set point to a second set point within a predetermined time period, as the manner controlled for the gas mixture performed at step 404. It is believed that low process pressure during the deposition process may assist forming crystalline structure in the film, thereby increasing the crystalline fraction in the resultant bulk intrinsic type microcrystalline silicon layer 118. Accordingly, the process pressure controlled during the intrinsic type microcrystalline silicon layer deposition process may be gradually ramped up so as to reduce the crystalline fraction formed in the bulk intrinsic type microcrystalline silicon layer 118. In one embodiment, the process pressure may be ramped up from 12 Torr to about 15 Torr at a time period between about 1000 seconds and about 1800 seconds.

The spacing of the substrate to the gas distribution plate assembly may be dynamically controlled as needed. In one embodiment, the spacing of the substrate may be gradually increased so as to reduce the crystalline fraction formed in the bulk intrinsic type microcrystalline silicon layer 118. For example, the spacing of the substrate may be increased from 600 mils to about 750 mils over a time period between about 1000 seconds and about 1800 seconds. It is noted that the process parameters as discussed above, including process pressure, RF power, spacing, gas flow rate, and the like, can all be dynamically controlled so as to maintain the film crystalline fraction at a desired range with the growth of the film thickness. The substrate temperature may be dynamically controlled, i.e., ramped up or ramped down, between about 50 degrees Celsius and about 300 degrees Celsius, such as between about 100 degrees Celsius and about 250 degrees Celsius, for example about 200 degrees Celsius.

By efficiently and dynamically controlling the flow rate of the gas mixture, the RF power and process pressure maintained during the deposition process, a desired film property, such as uniform crystalline fraction across the bulk intrinsic type microcrystalline silicon layer 118, may be obtained. By dynamically ramping up the silane flow and dynamically ramping down the RF power during the deposition process, a uniform film crystalline fraction may be obtained in the bulk intrinsic type microcrystalline silicon layer 118. In one embodiment, the resultant intrinsic type microcrystalline silicon layer may have a crystalline fraction greater than 40 percent, such as between about 45 percent and about 55 percent, or greater. As the film crystalline fraction and film crystalline uniformity improve, the photoelectric conversion efficiency may be improve about 50 percent to about 150 percent, resulting in significant increase in the device performance of the PV solar cell.

FIG. 5 is a top schematic view of one embodiment of a process system 600 having a plurality of process chambers 531-537, such as PECVD chamber 300 of FIG. 3 or other suitable chambers capable of depositing silicon films. The process system 500 includes a transfer chamber 520 coupled to a load lock chamber 510 and the process chambers 531-537. The load lock chamber 510 allows substrates to be transferred between the ambient environment outside the system and vacuum environment within the transfer chamber 520 and process chambers 531-537. The load lock chamber 510 includes one or more evacuatable regions holding one or more substrate. The evacuatable regions are pumped to facilitate insertion of substrates into the system 500 and are vented to facilitate removal of the substrates from the system 500. The transfer chamber 520 has at least one vacuum robot 522 disposed therein that is adapted to transfer substrates between the load lock chamber 510 and the process chambers 531-537. While seven process chambers are shown in FIG. 5; this configuration is not intended to be limiting as to the scope of the invention, since the system may have any suitable number of process chambers.

In certain embodiments of the invention, the system 500 is configured to deposit the first p-i-n junction 126, such as shown in FIG. 1, of a multi-junction solar cell. In one embodiment, one of the process chambers 531-537 is configured to deposit the p-type layer(s) of the first p-i-n junction while the remaining process chambers 531-537 are each configured to deposit both the intrinsic type layer(s) and the n-type layer(s). The intrinsic type layer(s) and the n-type layer(s) of the first p-i-n junction may be deposited in the same chamber without any passivation processes performed between the deposition steps. Thus, in one embodiment, a substrate enters the system through the load lock chamber 510, the substrate is then transferred by the vacuum robot into the dedicated process chamber configured to deposit the p-type layer(s). Next, after forming the p-type layer the substrate is transferred by the vacuum robot into one of the remaining process chamber configured to deposit both the intrinsic type layer(s) and the n-type layer(s). After forming the intrinsic type layer(s), and the n-type layer(s) the substrate is transferred by the vacuum robot 522 back to the load lock chamber 510. In certain embodiments, the time to process a substrate in the process chamber to form the p-type layer(s) is approximately 4 or more times faster, such as 6 or more times faster, than the time to form the intrinsic type layer(s) and the n-type layer(s) in a single chamber. Therefore, in certain embodiments of the system, the ratio of p-chambers to i/n-chambers is 1:4 or more, such as 1:6 or more. The throughput of the system including the time to provide plasma cleaning of the process chambers may be about 10 substrates/hr or more, for example 20 substrates/hr or more.

In certain embodiments of the invention, a system 500 may be configured to deposit the second p-i-n junction 128 such as shown in FIG. 1 of a multi-junction solar cell. In one embodiment, one of the process chambers 531-537 is configured to deposit the p-type layer(s) of the second p-i-n junction while the remaining process chambers 531-537 are each configured to deposit both the intrinsic type layer(s) and the n-type layer(s). The intrinsic type layer(s) and the n-type layer(s) of the second p-i-n junction may be deposited in the same chamber without any passivation process performed in between the deposition steps. In certain embodiments, the time to process a substrate within the process chamber to form the p-type layer(s) may be approximately 4 or more times faster than the time to form the intrinsic type layer(s) and the n-type layer(s) in a single chamber. Therefore, in certain embodiments of the system to deposit the second p-i-n junction, the ratio of p-chambers to i/n-chambers is 1:4 or more, such as 1:6 or more. The substrate throughput of the system, including the time to provide plasma cleaning of the process chambers, may be about 3 substrates/hr or more, such as 5 substrates/hr or more.

In certain embodiments of the invention, a system 500 is configured to deposit the WSR layer 112, as depicted in FIG. 1, that may be disposed between a first and a second p-i-n junction or a second p-i-n junction and a second TCO layer. In one embodiment, one of the process chambers 531-537 is configured to deposit one or more of the WSR layers, and another one of the process chambers 531-537 is configured to deposit the p-type layer(s) of the second p-i-n junction while the remaining process chambers 531-537 are each configured to deposit both the intrinsic type layer(s) and the n-type layer(s). The number of the chambers configured to deposit the WSR layer may be similar to the number of the chambers configured to deposit the p-type layer(s). Additionally, the WSR layer may be deposited in the same chamber configured to deposit both the intrinsic type layer(s) and the n-type layer(s).

In certain embodiments, the throughput of a system 500 that is configured for depositing the first p-i-n junction comprising an intrinsic type amorphous silicon layer has a throughput that is two times greater than the throughput of a system 500 that is used to deposit the second p-i-n junction comprising an intrinsic type microcrystalline silicon layer, due to the difference in thickness between the intrinsic type microcrystalline silicon layer(s) and the intrinsic type amorphous silicon layer(s). Therefore, a single system 500 that is adapted to deposit the first p-i-n junction, which comprises an intrinsic type amorphous silicon layer, can be matched with two or more systems 500 that are adapted to deposit a second p-i-n junction, which comprises an intrinsic type microcrystalline silicon layer. Accordingly, the WSR layer deposition process may be configured to be performed in the system adapted to deposit the first p-i-n junction for efficient throughput control. Once a first p-i-n junction has been formed in one system, the substrate may be exposed to the ambient environment (i.e., break vacuum) and transferred to the second system, where the second p-i-n junction is formed. A wet or dry cleaning of the substrate between the first system depositing the first p-i-n junction and the second p-i-n junction may be necessary. In one embodiment, the WSR layer deposition process may be performed in a separate system.

Thus, methods for forming an intrinsic type microcrystalline silicon layer with uniform crystalline fraction in a solar cell device are provided. The method utilizes dynamic control of process parameters utilized during the deposition process. The method advantageously produces an intrinsic type microcrystalline silicon layer having high crystalline fraction, crystalline uniformity and photoelectric conversion efficiency and device performance of the PV solar cell.

While the foregoing is directed to embodiments of the present invention, other and further embodiments of the invention may be devised without departing from the basic scope thereof, and the scope thereof is determined by the claims that follow.

What is claimed is:

1. A method for forming an intrinsic type microcrystalline silicon layer, comprising:
dynamically ramping up a silane gas supplied in a gas mixture to a surface of a substrate disposed in a processing chamber;
dynamically ramping down a RF power applied in the gas mixture supplied to the processing chamber, the gas mixture forming a plasma in the processing chamber; and
forming an intrinsic type microcrystalline silicon layer on the substrate in the presence of the plasma.

2. The method of claim 1, wherein the silane gas supplied in the gas mixture is ramped up linearly.

3. The method of claim 1, wherein the RF power applied in the gas mixture is ramped down linearly.

4. The method of claim 1, further comprising:
forming a seed layer prior to forming the intrinsic type microcrystalline silicon layer.

5. The method of claim 4, further comprising:
performing a hydrogen treatment process prior to forming the seed layer on the substrate surface.

6. The method of claim 4, wherein performing the hydrogen treatment process further comprises:
applying a RF power less than 150 milliWatts/cm² in the hydrogen treatment process.

7. The method of claim 1, further comprising:
dynamically ramping up a process pressure of the gas mixture disposed in the processing chamber.

8. The method of claim 7, wherein dynamically ramping up the process pressure further comprises:
ramping up the process pressure from about 12 Torr to about 15 Torr.

9. The method of claim 1, wherein dynamically ramping up the silane gas supplied in the gas mixture further comprises:
ramping up a ratio of a flow rate of the silane gas to a hydrogen gas supplied in the gas mixture from about 1:70 to about 1:80.

10. The method of claim 1, wherein dynamically ramping down the RF power applied in the gas mixture further comprises:
ramping down the RF power from 800 milliWatts/cm² to about 700 milliWatts/cm².

11. The method of claim 1, further comprising:
dynamically increasing a spacing of the substrate from about 600 mils to about 700 mils.

12. The method of claim 4, wherein forming the seed layer further comprises:
ramping up a silane gas flow rate supplied in the gas mixture; and
maintaining a steady hydrogen gas flow rate supplied in the gas mixture while ramping up the silane gas flow rate.

13. The method of claim 5, wherein forming the seed layer further comprises:
applying a RF power less than 400 milliWatts/cm² while forming the seed layer.

14. The method of claim 1, further comprising:
supplying the gas mixture to the processing chamber for a period between about 1000 seconds and about 1800 seconds.

15. A method for forming an intrinsic type microcrystalline silicon layer, comprising:
forming an intrinsic type seed layer on a substrate disposed in a processing chamber;
applying a RF power less than 400 milliWatts/cm² to maintain a plasma formed from a gas mixture while forming the seed layer;
subsequently forming an intrinsic type microcrystalline silicon layer on the substrate in the presence of the plasma, wherein the intrinsic type microcrystalline silicon layer is formed by dynamically ramping up a silane gas supplied in the gas mixture; and
dynamically ramping down a RF power applied in the gas mixture supplied to the processing chamber to form a plasma in the gas mixture.

16. The method of claim 15, wherein the step of dynamically ramping up the silane gas supplied in the gas mixture further comprises:
ramping up a flow ratio of the silane gas to a hydrogen gas supplied in the gas mixture from about 1:70 to about 1:80.

17. The method of claim 15, wherein the step of dynamically ramping down the RF power further comprises:
ramping down the RF power from 800 milliWatts/cm² to about 700 milliWatts/cm².

18. The method of claim 15, the step of dynamically ramping up the silane gas supplied in the gas mixture further comprises:
ramping up the process pressure from about 12 Torr to about 15 Torr.

19. The method of claim 15, further comprising:
performing a hydrogen treatment process prior to forming the intrinsic type seed layer on the substrate surface.

20. A method for forming an intrinsic type microcrystalline silicon layer, comprising:
supplying a first gas mixture onto a surface of a substrate disposed in a processing chamber to form an intrinsic type seed layer on the substrate, wherein a first gas mixture includes a silane gas and a hydrogen gas, the silane gas flow rate is ramped up and the hydrogen gas flow rate is maintained steady while supplying the first gas mixture; and
supplying a second gas mixture onto the surface of the substrate to form an intrinsic type microcrystalline silicon layer on the intrinsic type seed layer, wherein the silane gas flow rate is ramped up while supplying the second gas mixture and a RF power applied to the second gas mixture is ramped down while forming the intrinsic type microcrystalline silicon layer.
